(19) United States
(12) Patent Application Publication
(10) Pub. No.: US 2003/0178625 A1
(43) Pub. Date: Sep. 25, 2003

(54) Electronic write display projection system

(76) Inventors: Wen-Tsung Sun, Chiayii Hsien (TW); Shih-Chia Yu, Taipei (TW); Kuan Cheng Huang, Taoyuan (TW); Jen-Der Hsieh, Kaohsiung Hsien (TW)

Correspondence Address: J.C. Patents, Inc., Suite 250, 4 Venture, Irvine, CA, 92618, US

(21) Appl. No.: 10/104,907

(22) Filed: Mar. 22, 2002

(51) Int. Cl. H01L 29/04

(52) U.S. Cl. 257/72

(57) ABSTRACT

An electronic write display projection system for connecting with a host computer to form a computer system. A user may scribble down anything and transmit directly to the write display projection system. The electronic write display projection system includes a S liquid crystal display panel, a touch control panel and an application software component. When the computer system and a projection device are connected together, any written data input into the electronic write display projection system are immediately projected by the projection device to a curtain or a white screen. Moreover, the written data is stored inside the host computer for subsequent use.

### BACKGROUND OF THE INVENTION

1. Field of Invention

The present invention relates to an electronic projection system. More particularly, the present invention relates to an electronic write display projection system that permits direct projection of handwriting onto a projection screen.

2. Description of Related Art

A lecturer organizing a lecture often puts up pictures or notes through a projection system connected to a conventional computer system such as a notebook computer. The lecturer has to prepare all the necessary material before the lecture and project the material onto a white screen or a curtain because there is no way for the lecturer to write anything on the projection screen through the liquid crystal display (LCD). If the lecturers really want to provide some additional information or to make some alterations to the material displayed on the screen, they must move to the projection screen and scribble notes there. Since writing down notes on a curtain screen is very inconvenient, a white screen must be used. However, a white screen often may cause considerable reflection of the projected data and results in viewing difficulties. In addition, anything written down on the projection screen during lecture is not preserved for subsequent use.

In brief, drawbacks of a conventional projection system include:

1. Impossible to write down anything directly onto the liquid crystal display (LCD) of a note book computer and display the written material directly on the projection screen.

2. To post supplementary information or make some alterations, the lecturer must move to a white projection screen and scribble everything down there.

3. The white screen may produce so much back reflection that viewing becomes difficult.

4. Any supplementary information or alterations put up on the white screen is not retained after the lecture for reuse.

### SUMMARY OF THE INVENTION

Accordingly, one object of the present invention is to provide an electronic write display projection system. The electronic write display projection system permits a lecturer to write down anything directly into the projection system and project the written data onto either a white or a curtain screen. Hence, the lecturer no longer has to move to a white screen and scribble down anything there. In addition, anything written down into the projection system by the lecturer is preserved for subsequent use.

To achieve these and other advantages and in accordance with the purpose of the invention, as embodied and broadly described herein, the invention provides an electronic write display projection system for connecting with a host computer to form a computer system. A user may scribble down anything and transmit directly to the write display projection system. The electronic write display projection system includes a liquid crystal display panel, a touch control panel and an application software component. The liquid crystal display panel displays data. The touch control panel connects with the liquid crystal display panel. The touch control panel executes various displayed functions according to the area touched and accepts any data directly written onto the control panel. The application software component is stored inside the host computer for identifying and transferring data into the memory storage area inside the host computer.

In the embodiment of this invention, the data can be anything written down by the user. The written data is transferred to the memory area inside the host system. In general, the software component operates under the operating system of the host computer.

When the computer system and the projection device are connected together, data may project onto a projection curtain through the projection device. Moreover, the electronic write display projection system may integrate with the liquid crystal display.

Graphic figures may also be drawn and transferred into the electronic write display projection system. When the computer system and the projection device are connected together, any drawn figures may be projected onto a projection curtain through the projection device. In general, the figures are stored inside the memory unit of a host computer.

This invention also provides a computer system capable of accepting and processing directly written data. The computer system includes a host computer and an electronic write display projection system. The electronic write display projection system and the host computer are connected together. Data can be directly written down through the electronic write display projection system. The electronic write display projection system includes a liquid crystal display panel, a touch control panel and an application software component. The liquid crystal display panel displays data. The touch control panel connects with the liquid crystal display panel. The touch control panel executes various displayed functions according to the area touched and accepts any data directly written onto the control panel. The application software component is stored inside the host computer for identifying and transferring data into the memory storage area inside the host computer.

In brief, the electronic write display projection system according to this invention accepts directly written data. Hence, when the projection system equipment and a computer system are tied up together, a lecturer may write down anything directly into the electronic write display projection system so that the written data is projected onto either a curtain or a white screen. Consequently, the lecturer no longer has to move to a white screen and scribble down anything there. In addition, anything written down into the electronic write display projection system by the lecturer is preserved for subsequent use.

It is to be understood that both the foregoing general description and the following detailed description are exemplary, and are intended to provide further explanation of the invention as claimed.

### BRIEF DESCRIPTION OF THE DRAWINGS

The accompanying drawing is included to provide a further understanding of the invention, and is incorporated in and constitutes a part of this specification. The drawing illustrates embodiment of the invention and, together with the description, serves to explain the principles of the invention. In the drawing,

FIG. 1 is a schematic sketch of an electronic write display projection system according to one preferred embodiment of this invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

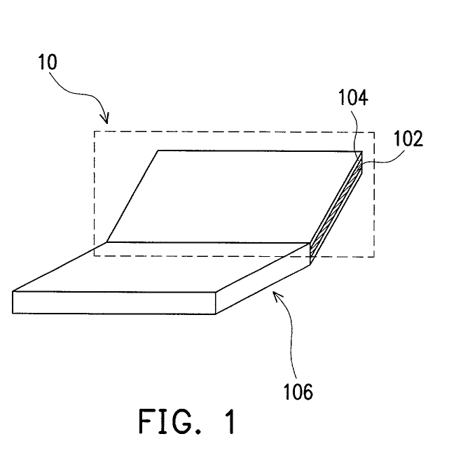

FIG. 1 is a schematic sketch of an electronic write display projection system according to one preferred embodiment of this invention. In FIG. 1, the electronic write display projection system 10 and the host computer 106 are joined together to form a notebook computer. The electronic write display projection system 10 has a liquid crystal display (LCD) panel 102 and a touch control panel 104. Furthermore, the electronic write display projection system 10 has an internal application software component stored inside the host computer 106. Functions of various elements constituting the electronic write display projection system 10 are further described below.

The liquid crystal display (LCD) panel 102 is a liquid crystal display board capable of showing both data text or graphic symbols.

The touch control panel 104 and the liquid crystal display panel 102 are integrated together. The touch control panel 104 includes a list of functional items that may be selected. A particular item may be selected and then executed by touching a corresponding area. In addition, the touch control panel 104 also accepts any directly written data or drawn figures.

The application software component is stored inside the host computer 106. The application software component operates under the operating system of the host computer 106. When a user writes data or draws figures on the liquid crystal display 102, the data or figures are accepted by the electronic write display projection system 10. The application software component identifies the written data or drawn figures and transfers the data and figures to the memory unit of the host computer 106 for storage. Moreover, the application software component stores up the written data in the original format style chosen by the user.

When the computer system of the electronic write display projection system and the projection device are connected together, a lecturer may write or draw directly on the liquid crystal display of the electronic write display projection system. The written data or drawn figures are immediately projected onto either a curtain or a white screen through the projection device. Thus, if the lecturer needs to provide some amendments or data corrections, one can do so without moving to the projection screen and scribbling over there. Moreover, the lecturer may write relevant lecture material directly onto the touch control panel of the electronic display projection system so that the written material is projected onto the projection screen while addressing an audience. Because the lecturer no longer needs to stand in front of the white screen and scribble data there, height and positioning of the screen is no longer a problem. An additional advantage of the electronic write display projection system is the capacity for holding any written or drawn material in memory so that the lecturer may distribute a copy of the written data or drawn figures to the audience electronically or on paper. Hence, the electronic write display projection system according to this invention is a convenient means of providing lecture material to all lecturers.

In conclusion, major advantages of this invention include:

1. The electronic display projection system accepts both written data and drawn figures. Any written data or drawn figures are immediately projected onto a curtain or a white screen through a projection device.

2. Written data and drawn figures are preserved within memory so that such material may be copied and distributed to relevant people on demand.

3. There is no need for a lecturer to move forward to the projection screen and scribble down any additional material or modification.

4. Immediate projection of scribbled lecture material onto a projection screen while talking animates the entire lecture.

5. Formal preparation of lecture material is unnecessary and the lecturer can easily coordinate writing and talking activities. Because writing on a white screen is rendered obsolete, height and position of the white screen is no longer a problem for the lecturer.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An electronic write display projection system that connects with a host computer to form a computer system, wherein data can be written into the electronic write display projection system, the electronic write display projection system comprising:
a liquid crystal display panel for displaying the written data;
a touch control panel connected to the liquid crystal display panel, wherein the touch control panel displays a list of functions that may be executed by touch selection and the touch control panel also serves as an interface for writing data into the electronic write display projection system; and
an application software component stored inside the host computer for identifying and transferring the written data to the host computer for storage.

2. The projection system of claim 1, wherein the written data is stored inside the host computer in a user's original writing style.

3. The projection system of claim 1, wherein the application software component operates under an operating system running within the host computer.

4. The projection system of claim 1, wherein written data is projected from a projection device to a curtain screen when the computer system and the projection device are connected together.

5. The projection system of claim 1, wherein the written data is stored inside a memory unit within the host computer.

6. The projection system of claim 1, wherein the electronic write display projection system may combine with a liquid crystal display.

7. The projection system of claim 1, wherein the electronic write display projection system also accept data of drawn figures.

8. The projection system of claim 7, wherein the drawn figures are projected from a projection device to a curtain screen when the computer system and the projection device are connected together.

9. The projection system of claim 7, wherein the data of drawn figures are stored electronically inside a memory unit within the host computer.

10. A computer system having an interface for accepting written data, comprising:
a host computer; and
an electronic write display projection system connected to the host computer, wherein data can be written into the electronic write display projection system, the electronic write display projection system further comprising:
a liquid crystal display panel for displaying the written data;
a touch control panel connected to the liquid crystal display panel, wherein the touch control panel displays a list of functions that may be executed by touch selection and the touch control panel also serves as an interface for writing data into the electronic write display projection system; and
an application software component stored inside the host computer for identifying and transferring the written data to the host computer for storage.

11. The computer system of claim 10, wherein the written data is stored inside the host computer in the user's original writing style.

12. The computer system of claim 10, wherein the application software component operates under an operating system running within the host computer.

13. The computer system of claim 10, wherein written data is projected from a projection device to a curtain screen when the computer system and the projection device are connected together.

14. The computer system of claim 10, wherein the written data is stored inside a memory unit within the host computer.

15. The computer system of claim 10, wherein the electronic write display projection system may combine with a liquid crystal display.

16. The computer system of claim 10, wherein the electronic write display projection system also accept data of drawn figures.

17. The computer system of claim 16, wherein the drawn figures are projected from a projection device to a curtain screen when the computer system and the projection device are connected together.

18. The computer system of claim 16, wherein the data of drawn figures are stored electronically inside a memory unit within the host computer.
